(19) United States
(12) Patent Application Publication
(10) Pub. No.: US 2004/0104729 A1
(43) Pub. Date: Jun. 3, 2004

(54) SYSTEM AND METHOD FOR SUPERVISION

(75) Inventors: Michael JOHANSSON, Lerum (SE); Mats BLOMSTRAND, Skovde (SE)

Correspondence Address: HOWREY SIMON ARNOLD & WHITE LLP, 1299 PENNSYLVANIA AVE., NW, BOX 34, WASHINGTON, DC, 20004, US

(73) Assignee: VOLVO LASTVAGNAR AB, Goteborg (SE)

(21) Appl. No.: 10/605,318

(22) Filed: Sep. 22, 2003

Related U.S. Application Data
(63) Continuation of application No. PCT/SE02/00422, filed on Mar. 8, 2002.

(30) Foreign Application Priority Data
Mar. 22, 2001 (SE) 0101003-2

(51) Int. Cl. G01R 31/00

(52) U.S. Cl. 324/504

(57) ABSTRACT

System and method for monitoring the functioning of electric components on a vehicle or a vehicle combination, where the system includes a control system, means for activating at least one electric component, means for allowing an operator to give at least one message to the control system, means for allowing the control system to give at least one message to the operator, and means for measuring at least one characteristic value for the component.

### CROSS REFERENCE TO RELATED APPLICATIONS

The present application is a continuation patent application of International Application No. PCT/SE02/00422 filed 8 Mar. 2002 which was published in English pursuant to Article 21(2) of the Patent Cooperation Treaty, and which claims priority to Swedish Application No. 0101003-2 filed 22 Mar. 2001. Both applications are expressly incorporated herein by reference in their entireties.

### BACKGROUND OF INVENTION

1. Technical Field

The present invention relates to a system and method for monitoring the functioning of electric components on a vehicle or a vehicle combination generally of the type disclosed in U.S. Pat. No. 4,866,390 which is expressly incorporated herein by reference for purposes of disclosure.

2. Background

A system for testing lamps on a vehicle is described in U.S. Pat. No. 4,866,390. This system consists of a portable box containing a battery, connection cable, a number of switches and an electronic circuit for sequentially controlling two relays. The system is intended to be connected to a trailer for checking the lamps of the trailer. The system includes switches for turning on certain lamps, for example reversing lights or parking lights, and a function for sequentially turning on indicators and brake lights. The idea of this is that an operator should be able to check all the lamps on a trailer himself or herself by only having to walk around the trailer once.

This system may perhaps function in some applications, but it has a number of obvious disadvantages. Firstly, it is intended only for testing lamps on a trailer. The lamps on the traction vehicle have to be tested in a conventional manner. Secondly, it is necessary for the operator to walk around the trailer each time that the test is to be performed. Thirdly, the test cannot be performed straight away when there is a connection between the trailer and the traction vehicle; the trailer must first be disconnected from the traction vehicle. Fourthly, the combination of traction vehicle and trailer is not tested. It is entirely possible that the lamps on the trailer function, but that the connection between the traction vehicle and the trailer is defective. Fifthly, it is intended for trailers in which indicators and brake lights use the same lamps. This means that the system has no application in, for example, Europe. Sixthly, the system is heavy and unwieldy, and finally it is an expensive solution.

### SUMMARY OF INVENTION

An object of the invention is therefore to produce a system for monitoring electric components on a vehicle, or vehicle combination, which is simple to use and to provide a method for monitoring electric components on a vehicle, or vehicle combination in as simple a manner as possible.

In at least one embodiment, the invention takes the form of a system for monitoring the functioning of electric components on a vehicle, or a vehicle combination such as a tractor-trailer combination, comprising (including, but not limited to) a control system having (1) means for activating at least one electric component, (2) means for allowing an operator to give a message to a control system, and (3) means for allowing the control system to give a message to the operator. The object of the invention is achieved by virtue of the fact that the system includes means for measuring at least one characteristic value for the relevant electric component.

In an alternative embodiment, the invention takes the form of a method that achieves the objects outlined above by starting a monitoring procedure, activating at least one electric component, measuring at least one characteristic value for said component, allowing the control system to give at least one message to an operator and allowing the operator to give at least one message to the control system.

By virtue of this embodiment, the system includes a control system having means for activating at least one electric component, means for giving at least one message to the operator, means for an operator to give at least one message to the control system and means for measuring at least one characteristic value for the relevant component. With such a system, at least one electric component can be activated and the system can give information to the operator about the functioning of the component and the operator can inform the system whether this functioning is correct or incorrect.

In an advantageous embodiment of the invention, the system includes means for saving at least one measured characteristic value. The advantage of this feature is that an operator can see deviations between a measured characteristic value and a saved nominal value.

In another advantageous embodiment of the invention, the system includes means for comparing a saved nominal value with a measured characteristic value. The advantage of this is that the system can detect deviations between a measured characteristic value and a saved nominal value.

In another advantageous embodiment of the invention, the system is integrated into an existing control system of the vehicle. The advantage of this is that the system is simpler to use and the system costs less.

In another advantageous embodiment of the invention, the system includes means for saving one or more data set(s), where a data set contains at least one characteristic value. A data set can then correspond to a part of a vehicle combination. The advantage of this is that nominal values for a number of different trailers can be saved, which makes the procedure easier when various trailers are used.

In yet another advantageous embodiment of the invention, the system comprises means for saving historical values for at least one component in one or more historical data set(s). The purpose of this is to enable monitoring of how long and/or often a component has been activated.

In still another advantageous embodiment of the invention, the system comprises means for, with the aid of a historical data set, predicting the service life of a component. The purpose of this is for it to be possible to estimate when it is time to change components.

An advantageous embodiment of the method form of the invention which is used for testing electric components on a vehicle, or a vehicle combination, comprises the steps of (1) starting a monitoring procedure, (2) activating at least one electric component, (3) measuring at least one characteristic value for the component, (4) allowing the control system to give at least one message to an operator and (5) allowing the operator to give at least one message to the control system. The advantage of this embodiment is that it gives an operator information about the functioning of a component.

In an advantageous embodiment of the inventive method, at least one characteristic value for the component is saved. The advantage of this is that an operator can see deviations between a measured characteristic value and a saved nominal value.

In another advantageous embodiment of the inventive method, a measured characteristic value is compared with a saved nominal value and/or with a saved maximum and/or minimum value. The advantage of this is that the system can detect deviations between a measured characteristic value and a saved nominal value and/or that it is possible to detect states which are not permitted, for example a short circuit or an interruption.

In another advantageous embodiment of the invention, the method includes the step of, if the measured value differs from the saved nominal value and/or is smaller or, respectively, greater than the saved minimum and maximum values, giving a message to an operator and/or saving an error message. The advantage of this is that an operator can obtain information about the functioning of a component.

In still another advantageous embodiment of the invention, the method includes the step of monitoring a component every time the component is activated and/or, when the component is already activated, monitoring the component with a predefined time interval. This makes it possible, during operation as well, to detect states which are not permitted.

In yet another advantageous embodiment of the invention, the method comprises a user state which, in the course of an adjustable time interval, activates a component or a number of components sequentially. This affords an operator the opportunity of inspecting the components visually.

In still yet another advantageous embodiment of the invention, the user state can be initiated and/or stepped through using a remote control. This affords an operator the opportunity of operating the system outside the vehicle.

In another advantageous embodiment of the invention, the components which are to be activated in the user state can be selected by an operator. This makes it possible for an operator to determine which components are to be tested.

In yet another advantageous embodiment of the invention, the method can be divided into a number of part operations, where a part operation can test a part of the vehicle or the vehicle combination. This makes it possible to test only a part of a vehicle combination.

In still yet another advantageous embodiment of the invention, a part operation can be initiated automatically when a particular predefined event takes place. This makes it possible for the system to perform a test of a trailer automatically when it is attached.

In another advantageous embodiment of the invention, the method includes the step of saving characteristic values for a part operation in a special data set. This makes it possible to save characteristic values for a number of trailers, for example all the trailers owned by a haulage contractor.

In still another advantageous embodiment of the invention, it is possible to select one of a number of data sets of saved nominal values for comparing the measured characteristic values with. This makes it possible to test a known trailer in a simple manner.

In still another advantageous embodiment of the invention, historical values for a component are saved in a historical data set. The purpose of this is for it to be possible to monitor how long and/or often a component has been activated.

In yet another advantageous embodiment of the invention, the service life of a component is predicted with the aid of a historical data set. The purpose of this is for it to be possible to estimate when it is time to change a component; that is to say, to change the component before it fails.

In still yet another advantageous embodiment of the invention, the method includes the step of transferring at least one data set of characteristic values for a part operation and/or at least one historical data set to a central database. The purpose of this is for it to be possible to follow up a vehicle centrally as well.

### BRIEF DESCRIPTION OF DRAWINGS

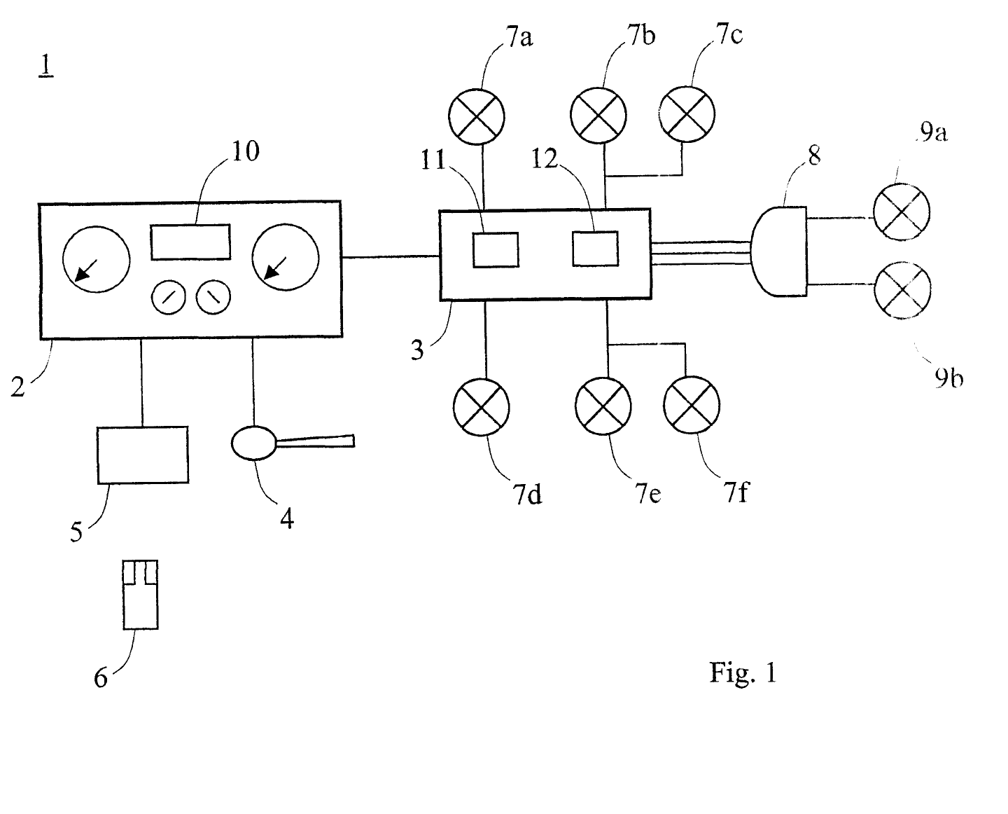

The invention will be described in greater detail below with reference to illustrative embodiments exemplified in the accompanying drawing, in which FIG. 1 shows a system configured according to the teachings of the invention disclosed herein.

### DETAILED DESCRIPTION

The illustrative embodiments of the invention with developments (versions or variations) described below are to be seen as only examples, and are in no way to be considered as limiting for the scope of protection of the patent claims.

A system for monitoring electric components configured according to the invention is for advantageous integration into a vehicle, for example a truck. The vehicle can be adapted so as to be capable of being attached and electrically connected to one or more additional vehicle(s), for example trailer arrangements on towing tractor rigs.

In this context, the sited electric components are intended to comprise (include) all types of electric component where the functioning can be checked by an operator, for example lamps, light indicating elements, signal horn, semiconductor elements, electric valves, electric motors and electric magnets. In the described examples, lamps will be used as an exemplary embodiment of an electric component in this portion of the description. Also for purposes of the present description of the invention, vehicle means is not only contemplated to include terrestrial vehicles such as trucks, tractor-trailers, trackbound vehicles like trains or trams, but also other types of vessels such as boats and ships. In this context, a vehicle combination includes combinations of several vehicles of the nature described above, for example a truck with one or more trailer(s) or an underground train consisting of a locomotive and a number of carriages.

The driver of, for example a truck, normally has to check that all the lamps on the vehicle or the vehicle combination are functioning before a run begins. In some cases, a vehicle combination consists of a trailer truck and a trailer which is never changed, and in some cases a trailer may be changed several times a day. As it is the driver who is responsible for assuring that the lamps are functioning even on hired trailers, it can take a long time to complete such a check. A driver normally has to walk around the vehicle combination twice, and moreover lock the brake with a rod or the like so as to be able to perform the check alone. This is of course time-consuming, and there is a great risk of the check being performed inadequately or of it not being performed at all.

Regarding the example of the lights on a tractor-trailer combination, one or more characteristic value(s) can be measured as being indicative of the condition of the light(s). Of these characteristic values, one value, a number of values or all of the values can be saved in a memory as the nominal value(s) for a component. The measured characteristic value(s) can also be compared with one or more saved nominal value(s) for the component in question. For the sake of simplicity, reference will be made here to one characteristic value.

In a first illustrative embodiment, the system can be integrated into a control unit in, for example, of a truck. FIG. 1 schematically represents a system 1 configured according to one illustrative embodiment of the invention. It comprises an instrument 2, a light control module 3, an input unit 4, a receiver 5 for a remote control, a remote control 6, a number of lamps on the truck 7a-7f, a trailer connection 8 and a number of lamps on the trailer 9a-9b. The instrument 2 comprises a display 10 and the control unit (not shown). The light control module 3 comprises a measurement module 11 and a drive module 12.

The system can of course also consist of additionally installed equipment consisting of separate units, but it is advantageous in terms of cost to integrate the system into the existing electronic control system. A monitoring procedure can be performed, for example, every time the vehicle is started, every day or according to another suitable periodicity.

The drive module 12 comprises one or more drive stage(s) (not shown) which can each activate an electric component. Such a drive stage can be, for example, a relay or a power semiconductor which is controlled from the control unit. The drive stages can either be placed together in a module which is positioned centrally, for example in the light control module 3, or they can be located separately in or in proximity to the electric component to be driven. Control of a drive stage can be either discrete with a control signal for each drive stage or via a data bus where the control signal is coded in a suitable manner, for example via a CAN bus with an appropriate protocol.

The display 10 is used for giving messages to the operator. It is not necessary for a display to be used for giving messages to the operator, but other means for giving messages are also conceivable, for example a buzzer, a lamp, a light indicating means, a voice message, a vibration module or other types of displays. Advantageously, an existing graphic display can, however, be used.

The input unit 4 is provided to enable the operator to give messages to the control system. Such an input unit often consists of a number of switch elements, suitably arranged so that they can be used in a simple and logical manner. They can be integrated into, for example, a lever which is also used for other types of messages. Other input possibilities are also conceivable, for example voice recognition or a keyboard.

The light control module 3 comprises a measurement module 11 for measuring at least one characteristic value for the component in question. This module can comprise, for example, an A/D converter or a pulse counter. Characteristic values can consist of one or more of the quantities for current, voltage, resistance, time or of a combination of these quantities. For example, the characteristic values for a motor can be resistance and a function of current change per unit of time. In the examples described here, current is used as the characteristic value.

The system also comprises components which are well known to the person skilled in the art and are not described in greater detail, but, for example, would include memories, comparators, bus circuits and the like.

When the system has activated an electric component, the system measures at least one characteristic value for this component. A characteristic value is a value which describes the instantaneous value for the component. A characteristic value can be compared with a saved value for this component. Saved values can be, for example, nominal value(s), maximum permitted value(s) and minimum permitted value(s). In this regard, a nominal value is that which describes correct electrical functioning of the component.

In one illustrative embodiment, the electric component can be, for example, the lamp circuit for the right-turn signal or indicator. The system activates the right indicator and measures, for example, how much current the lamps in this lamp circuit draw. For example, a lamp circuit for an indicator on a typical traction vehicle can consist of three 21 W lamps 7a-7c; one front 7a and two rear 7b-7c. Exemplarily, such a lamp circuit might draw approximately 2.3 amps with a system voltage of 28 volts. As this is the theoretical value for this lamp circuit, that is to say the value with which a measured characteristic value is to be compared, this value can be saved as the nominal value for this component.

A saved nominal value can be obtained in various ways. One way is to pre-program the value in the final station in production (final stages of production). This is sufficient when the vehicle is delivered directly to the end customer in a finished state. The vehicle often goes first to a constructor (party that assembles the vehicle), who mounts additional equipment before the vehicle is delivered to the end customer. The system therefore also comprises a learning state where an electric component is activated, one or more characteristic value(s) is or are measured and where the operator approves this value or these values as the nominal value(s), which is or are then saved as the nominal value(s) in a memory.

A minimum permitted value can be, for example, a value which corresponds to, for example, the minimum permitted current consumption which is possible for the vehicle to meet certain legal requirements. For example, the minimum permitted value for an indicator of a traction vehicle may be 1.3 A (amperes). This corresponds to two 21 W lamps, one front and one rear, which is the minimum requirement in Europe. A maximum permitted value can be, for example, the maximum load value for the drive stage, for example 10 A, for a power semiconductor.

If the difference between the measured characteristic value and the saved nominal value is not greater than a suitable factor, for example 10-20%, of the nominal value, the system can approve the functioning. The system can then give a message that the component is serviceable (suitable for operation). If the measured characteristic value is outside the limit for approval, the system gives an error message to the effect that the component is not serviceable (functioning properly). The operator can then inspect the component. If the component is defective, the fault can be attended to, for example, changing the faulty lamp. When the defect has been attended to, the system will measure a characteristic value which lies within the limit for approving the component.

For example, the measured characteristic value for a right indicator with a system voltage of 24 V may in this example be 2.6 A. As the saved nominal value is 2.3 A, the difference is 0.3 A. As all the lamps are operable in this example, the deviation between the measured characteristic value and the saved nominal value is due to a voltage variation, and the measured characteristic value should be approved. In this case, the factor which sets the limit for when the measured characteristic value is to be approved must be greater than 13%. It is appropriate to take, for example, voltage variations, lamp deviations and the like into consideration when this factor is determined.

A special case arises when a component cannot be attended to directly. If the vehicle is still roadworthy, the operator can approve the measured characteristic value for the defective functioning. This may occur, for example, when a vehicle has a number of lamps for the same function, for example two lamps for an indicator 7b-7c on one side at the rear. If one of these lamps fails, for example 7b, the vehicle is still roadworthy. This may also occur if the tested component is a component which is not compulsory, for example wind deflector illumination. The system can then either save this measured value as the nominal value, or retain the nominal value it had previously.

If the measured characteristic value lies below the minimum permitted value for a component, the fault must be attended to. This may otherwise lead to the vehicle not being roadworthy or to the vehicle being damaged if it is driven. If the measured value lies above the maximum permitted value, there is either a short circuit or an overload, and the fault must again be attended to. It is possible to link this information to, for example, a starting lock or to send a message to a call center.

The components to be tested are saved in a list. The system activates one component at a time until the entire list has been worked through. It is possible to allow an operator to select which components are to be included in the test. It is also possible for important components, for example components which are important for road safety or components vital for operation of the vehicle, to have to be included in the list.

When a known vehicle or a known vehicle combination is to be checked, the time for which each component is activated can be short, for example 0.5-2.0 seconds per component. It is important that the activation time is long enough that the component being tested has time to reach a steady operating state, otherwise the measured characteristic will be incorrect. The activation time is adapted to the component to be tested, and the system can therefore have different activation times for different components. For lamps, for example, which have a very high starting current, it is important that this time is long enough that the lamps have time to heat up. For a motor which drives a pump, for example, a state of equilibrium must be achieved, which may result in the activation time having to be longer than for, for example, a lamp.

In a further development (variation) of the above-described illustrative embodiment, the system comprises (includes, but is not limited to) a user state which can be used when a new vehicle or a new vehicle combination is to be checked. In the user state, the activation time for each component can be selected by an operator to be, for example, 4-10 seconds. In the user state, each component is activated for the predetermined activation time, and the entire list of components is worked through sequentially. The operator can then walk around the vehicle at the same time and verify that all the components are properly operating. If the components are serviceable (properly operating), the operator can, after all components have been activated, give an approval to the system. The system can then save these values as the nominal values for this vehicle combination. It is advantageous not to permit nominal values which lie outside the maximum and minimum values.

In the user state, it is possible to select a special state for stepping through the list of components. In this state, a component is activated until the operator either turns off the component or steps to the next component in the list. This can be done either using the usual input means 4, or using, for example, a remote control 6 which communicates with the control system via a receiver 5. This state can also be used for fault detection on a component.

In a second development of the first illustrative embodiment, it is advantageous to save nominal values for each vehicle in separate data sets. In this way, the nominal values for the first vehicle in the combination (the traction vehicle) are saved in one data set, and the nominal values for one or more second vehicles of the combination (different trailers) are each stored in their own data sets. This means that the functions of the traction vehicle can be checked separately, for example each time the vehicle starts, without the driver having to walk around the vehicle in order to check the components.

In this development, it is possible to save a number of data sets which each correspond to a trailer. This means that, for example, all the traction vehicles at a haulage contractor's can have the nominal values for each trailer saved. The driver of a traction vehicle can then, when attached a particular trailer, select that trailer from a list. Exemplarily, this selection can be made from a menu. The trailer selected can then be tested rapidly and simply without the driver having to walk around the vehicle combination. The nominal values for each trailer can be saved in its own data set in a database at the haulage contractor's. The data sets which correspond to the trailers which a traction vehicle is capable of attaching to can be transferred to the traction vehicle from the database.

A test of an attached trailer can be initiated either automatically or via a menu selection. It is possible to set the system so that it senses whether a trailer has been attached. This can be done, for example, by a test being performed each time the traction vehicle has reversed in order to check whether a new electric circuit has been connected. The system can also monitor the current consumption in the drive stages which drive the trailer and in this way initiate a test of the trailer.

In a third development of the first illustrative embodiment, the monitoring function is active when the vehicle is in operation as well. For example, the system can compare the measured characteristic value for a component with the nominal saved value for the component every time the component is activated and/or, when the component is already activated, compare the measured characteristic value with the nominal saved value for the component at even time intervals which are predefined. If a deviation is detected, an error message can be generated which can, for example, be shown via the usual message system of the vehicle on a display. At the same time, a message can be saved in a special error data set.

In a fourth development of the first illustrative embodiment, a plurality of values for a component are saved in a historical data set. This historical data set contains information about the operating conditions for the component. This may be, for example, the time when the component was changed, the operating time of the component, the number of activations, the maximum system voltage during operation, the operating time of the vehicle and the like. This information can be used for predicting the service life of a component.

When a service is carried out, use is made of the historical data set for calculating the operating time of the components. Depending on the component, the calculated operating time can be weighted with one or some of the other values in the historical data set, for example the number of activations, or with other values which may affect the service life of the component, for example where and how the vehicle is used. For example, it is advantageous to weight the operating time of a dipped light lamp or rear light lamp with the system voltage; it is advantageous to weight the operating time of an indicator lamp or a brake light with the number of activations. It can moreover be advantageous to take the area of application of the vehicle into consideration; for example, there is a considerably greater risk of a lamp shaking to pieces on a construction vehicle than on a traction vehicle which is driven on main roads. The weighted calculated operating time of a component is then compared with statistical values for, for example, service life and standard deviation for the component. This comparison is made in order to calculate a probability for when a given component will fail.

The probability for when a component will fail is then compared with the service interval for the vehicle in question. For example, the service interval of a typical traction vehicle may be 30,000 kilometers, which may mean that the vehicle is in for service every other month. If the probability of a component failing before the next scheduled service is greater than a predefined probability, the component in question is changed.

With a prediction system as above, unwanted stops will decrease considerably at the same time as the road safety and reliability of a vehicle will increase. The service costs of the vehicle may also decrease.

The historical data set can also be saved in, for example, a central database at a haulage contractor's. This means that the history of trailers which are towed by a number of traction vehicles can be monitored as well. It is also possible to transfer the historical data set to, for example, a haulage contractor's via, for example, a fleet management system.

In a first illustrative embodiment of the method according to the invention for monitoring the functioning of electric components on a vehicle or a vehicle combination, at least one electric component is activated, a characteristic value is measured for the component, the characteristic value is compared with a saved nominal value, and a message is given to an operator about whether or not the functioning of the component is correct.

This illustrative embodiment can include the steps of (1) activating an electric component, (2) measuring a characteristic value for the component, and (3) comparing the characteristic value with a saved nominal value. If the value is within a predefined margin of error, this component is approved and, if the value is outside, information about this is saved in an error data set.

These steps are repeated until all the components have been tested. An appropriate message is then given to the operator. If all the components are approved, an appropriate message to this effect is sent; if one or more component(s) are faulty, a similarly appropriate message is conveyed. As an example, the contents of the error data set may be shown to the operator. The operator may then acknowledge the message using the input unit. If a component is faulty, the operator can investigate and attend to the fault.

In a first development of this described method, the step of comparing the measured characteristic value with a saved maximum and/or minimum value is conducted. If the measured characteristic value is smaller or, respectively, greater than the saved minimum and maximum values, the system gives a message to the operator and/or saves an error message in an error data set. This results in a detected error generating an error message which can on the one hand be shown to an operator of the vehicle, and on the other hand be saved for use in service or for following up the vehicle. In this case, the system can detect states which are not permitted of a component or of the connections to the component, for example an interruption or a short circuit.

In a second development of the method, the method further comprises a user state which, during a predefined activation time, activates a function or a number of functions sequentially. This activation time can be defined by the operator and makes it possible to adapt the test procedure to the vehicle or the vehicle combination to be tested. For example, it takes a longer time to walk around a long vehicle combination than a short one, and the time interval for which a component is activated then needs to be adapted in an appropriate manner.

This user state can be used by an operator when a vehicle or a vehicle combination is to be checked for the first time or when a component is changed or newly installed. In this user state, the components are activated sequentially, and the operator can check that all the components are serviceable. If all the components are serviceable, the operator gives an approval to the system which can then save the measured characteristic value for a component as the nominal value for the component in a data set.

It is possible to select a manual activation state, when a component is activated until the operator turns off the component or steps to the next component in the list. This can be done either using the usual input unit or using, for example, a remote control. The user state can also be used for fault detection on a component.

In a third development of the method, the method can be divided into a number of part operations, where a part operation can test a part of the vehicle or the vehicle combination. This can be used, for example, when a traction vehicle tows a number of different trailers. The nominal values for each trailer can either be saved in a data set the first time the trailer is attached to the traction vehicle or be transferred to the traction vehicle from a database. Each data set is suitably saved under a user-defined name in a list so that it is easy to find next time the same trailer is attached to the traction vehicle. The test of the trailer then takes place rapidly and easily without the operator having to personally check all the components. A test of a trailer can be initiated automatically, for example when the trailer is attached to the traction vehicle, or it can be initiated by the operator via a menu selection.

In a fourth development of the method, an operator can select which components are to be included in the list of components to be tested. This means that the operator can adapt the test procedure to, for example, the vehicle or the vehicle combination to be tested. For example, only components which affect road safety can be included in a list, or components which are required only in certain countries can be included in a list. It is possible to have a number of lists from which to select.

In a fifth development of the method, a component is monitored each time the component is activated and/or, when the component is already activated, the component is monitored with a predefined periodicity. This means that components can be monitored not only when the system is initiated, but also during operation.

In a sixth development, the method also includes the step of monitoring historical values of a component, for example the operating time or the number of activations of the component. This means that the system can give a message to the driver when the estimated service life is approaching its end or has been exceeded. This means that the driver can change a component at a suitable opportunity instead of being forced to do so when the component has failed. For example, a driver can be informed that a front lamp ought to be changed within a week.

In a seventh development, the method also includes the step of saving historical values for a component in a historical data set. Historical values can be, for example, the time when the component was changed, the operating time of the component, the number of activations, the maximum system voltage during operation, the operating time of the system and the like. This means that a component, for example when a service is carried out, can be changed when the probability of the component failing before the next scheduled service is greater than a predefined probability. This can make the service both more simple and less expensive, while at the same time reducing unplanned vehicle service stops.

In an eighth development, the method also includes the step of the historical data set being transferred to and saved in, for example, a central database at a haulage contractor's. This means that the history of a trailer which is towed by a number of traction vehicles can be monitored as well. The transfer of the historical data set can take place by, for example, a cable connection, a wireless radio system or via a fleet management system.

It should be appreciated that the invention is not to be regarded as being limited to the illustrative embodiments described above, but a number of further variants and modifications are conceivable within the scope of the following patent claims. For example, the system can be used not only for trucks, but for all types of vehicle including private cars, construction machines, boats, trains and the like. The method is not even limited to vehicles, but can for example, be utilized in land-based operations such as for monitoring/evaluating street lighting or other types of functions in and around buildings, or stand-alone facilities.

1. A system (1) for monitoring the functioning of electric components on a vehicle or a vehicle combination comprising:
a control system, an instrument (2), means (3) for activating at least one electric component (7, 9), means (4) for allowing an operator to give at least one message to the control system, means (10) for allowing the control system to give at least one message to the operator, and means (11) for measuring at least one characteristic value for said electric component (7, 9), said means (10) for allowing the control system to give at least one message to the operator is integrated into the instrument (2), the system (1) is integrated into the instrument (2), and the system (1) is integrated into an existing control system.

2. The system as recited in claim 1, wherein the system further comprises:
means for saving at least one measured characteristic value.

3. The system as recited in claim 1, wherein the system further comprises:
means for comparing at least one measured characteristic value with at least one saved nominal value.

4. The system as recited in claim 1, wherein the system further comprises:
means for saving at least one characteristic value in one or more data set(s), where a data set contains at least one characteristic value and where the characteristic values in a data set correspond to the characteristic values for a vehicle.

5. The system as recited in claim 1, wherein the system further comprises:
means for saving at least one historical value for at least one component in at least one historical data set.

6. The system as recited in claim 5, wherein the system further comprises:
means for, with the aid of a historical data set, predicting the service life of a component.

7. The system as recited in claim 5, wherein the system further comprises:
means for transferring one or more historical data set(s) to a central unit.

8. A method for monitoring the functioning of electrical components on a vehicle or a vehicle combination, the method comprising:
starting a monitoring procedure;
activating at least one electric component;
measuring at least one characteristic value for said component;
allowing the control system to give at least one message to an operator via a means integrated in an instrument, and
allowing an operator to give at least one message to a control system via a menu system.

9. The method as recited in claim 8, further comprises:
saving at least one measured characteristic value for said component.

10. The method as recited in claim 8, further comprises:
comparing at least one measured characteristic value with at least one saved nominal value for said component; and
comparing at least one measured characteristic value with at least one saved maximum and/or minimum value for said component.

11. The method as recited in claim 8, further comprises:
giving one or more message(s) to an operator and/or saving one or more error message(s) when at least one measured characteristic value differs from at least one saved nominal value by more than a predefined factor and/or is smaller than at least one saved minimum value and/or is greater than at least one saved maximum value,

12. The method as recited in claim 8, further comprises:
monitoring a component every time the component is activated and/or, when the component is already activated, monitoring the component with a predefined time interval.

13. The method as recited in claim 8, further comprises:
activating a component or a number of components sequentially in a user state during the course of an adjustable time interval.

14. The method as recited in claim 13, wherein the user state can be initiated and/or stepped through using an input unit and/or a remote control.

15. The method as recited in claim 13, wherein the components which are to be activated in the user state can be selected by an operator.

16. The method as recited in 15, further comprising:
dividing the method into a number of part operations, where a part operation can monitor a part of the vehicle or the vehicle combination.

17. The method as recited in claim 16, wherein a part operation can be initiated automatically when a particular predefined event takes place.

18. The method as recited in claim 17, further comprising:
saving characteristic values for a part operation in a data set.

19. The method as recited in claim 17, further comprising:
selecting one of a number of data sets of saved nominal values for comparing the measured characteristic value.

20. method as recited in claim 19, further comprising:
saving historical values for at least one component in at least one historical data set.

21. The method as recited in claim 20, further comprising:
predicting the service life of a component with the aid of a historical data set.

22. The method as recited in claim 21, further comprising:
transferring at least one data set of characteristic values for a part operation and/or at least one historical data set to a central database.
